(19) United States
(12) Patent Application Publication
(10) Pub. No.: US 2026/0318991 A1
(43) Pub. Date: Oct. 15, 2026

(54) SEMICONDUCTOR DEVICE

(71) Applicant: Renesas Electronics Corporation, Tokyo (JP)

(72) Inventors: Yukihiro HAYASHI, Tokyo (JP); Toshihiko FUNAKI, Tokyo (JP)

(21) Appl. No.: 19/556,469

(22) Filed: Mar. 4, 2026

(30) Foreign Application Priority Data
Apr. 9, 2025 (JP) 2025-064343

(51) Int. Cl. G01R 31/3185; G01R 31/319

(52) U.S. Cl. CPC G01R 31/318536; G01R 31/318572; G01R 31/31908

(57) ABSTRACT

A semiconductor device includes a control circuit that generates a signal in response to a test execution instruction, and a plurality of function blocks. At least one of the plurality of function blocks includes a sequencer and requires a test setting before executing a test. The sequencer receives the signal generated by the control circuit and performs a test setting operation for the function block in response to the signal.

### CROSS-REFERENCE TO RELATED APPLICATIONS

The disclosure of Japanese Patent Application No. 2025-064343 filed on Apr. 9, 2025, including the specification, drawings and abstract is incorporated herein by reference in its entirety.

### BACKGROUND

The present invention relates to a semiconductor device.

There are disclosed techniques listed below.

[Patent Document 1] PCT International Publication No. 2000/073809

Semiconductor devices that include one or more IP (Intellectual Property) components have been known. An IP is a functional block that is a circuit designed for a specific function. Also, an electronic circuit board on which such semiconductor devices are implemented and connected to each other known. Patent Document 1 discloses a semiconductor integrated circuit (semiconductor device) including a plurality of IPs.

### SUMMARY

Recently, semiconductor devices are often designed to comply with the JTAG (Joint Test Action Group) specified by the IEEE 1149.1 standard. Moreover, a variety of IPs are provided by IP vendors. On the other hand, among the IPs, there are those for which tests specified by JTAG cannot be executed without specific settings. That is, the semiconductor device having such IPs cannot execute the tests specified by JTAG as is.

In light of the above circumstances, there is a demand for technology that enables the execution of tests specified by JTAG in semiconductor devices that contain functional blocks requiring specific settings during tests.

Other problems and novel features will become apparent from the description herein and from the accompanying drawings.

A semiconductor device according to one embodiment comprises a control circuit that generates a signal in response to a test execution instruction and a plurality of function blocks. At least one of the plurality of function blocks includes a sequencer. The function block requires a test setting before executing a test. The sequencer receives the signal generated by the control circuit and performs a test setting operation for the first function block in response to the signal.

A semiconductor device according to one embodiment includes a JTAG control circuit configured to generate an instruction signal in response to a test execution instruction, a plurality of function blocks including a first function block, a test signal shift in terminal, and a test signal shift out terminal. The first function block includes a test data register configured to set a status of the first function block, a boundary scan register coupled between the test signal shift in terminal and the test signal shift out terminal and receiving a test signal through the test signal shift in terminal, and a sequencer configured to store test setting data and send the test setting data to the test data register in response to the instruction signal from the JTAG control circuit to set the status of the first function block for the boundary scan test.

According to the above embodiment, a semiconductor device having functional blocks requiring specific settings during testing enables the execution of tests specified by JTAG.

### BRIEF DESCRIPTION OF THE DRAWINGS

FIG. 1 is a diagram showing a configuration example of the electronic circuit board according to the first embodiment.

FIG. 2 is a diagram showing a hardware configuration example of the semiconductor chip according to the first embodiment.

FIG. 3 is a diagram showing a configuration example of the functional blocks of the semiconductor chip according to the first embodiment.

FIG. 4 is a diagram showing the process flow of the semiconductor chip or electronic circuit board according to the first embodiment.

FIG. 5 is a diagram showing a configuration example of the functional blocks of the semiconductor chip according to the second embodiment.

FIG. 6 is a diagram showing the process flow of the semiconductor chip or electronic circuit board according to the second embodiment.

FIG. 7 is a diagram showing a configuration example of the electronic circuit board according to the third embodiment.

FIG. 8 is a time chart showing each signal of the electronic circuit board according to the third embodiment.

FIG. 9 is a diagram showing a configuration example of the electronic circuit board for comparison according to the third embodiment.

FIG. 10 is a timing chart showing each signal of the electronic circuit board for comparison according to the third embodiment.

FIG. 11 is a diagram showing a configuration example of the semiconductor chip according to the third embodiment.

FIG. 12 is a diagram showing the configuration of a related semiconductor device.

### DETAILED DESCRIPTION

Now, the embodiments will be described, but first, an explanation of the considerations by the inventor will be presented. The explanation of the considerations includes the configuration of the standard semiconductor device that serves as a comparison in relation to the semiconductor device proposed in this application. Subsequently, the embodiments of the semiconductor device proposed in this application will be described.

In the following embodiments, the same or corresponding components are denoted by the same reference numerals, and repetitive explanations are omitted except when necessary.

In the following embodiments, "semiconductor chip" is an example of the "semiconductor device" in this disclosure. "Boundary scan test" is an example of "test" in this disclosure. "MUX (Multiplexer)" is an example of "switching circuit" in this disclosure. "JTAG control circuit" is an example of "control circuit" in this disclosure. " Test Data Register (TDR) setting" is an example of "test setting operation" in this disclosure. "TDR setting data" is an example of "test setting data" in this disclosure.

### Considerations by the Inventors

### Problems with Semiconductor Devices Complying with JTAG

JTAG is known as the standard that the semiconductor devices should comply for testing an electronic circuit board. Under JTAG, a boundary scan test is generally executed when an electronic circuit board is powered on or rebooted.

Boundary Scan Test is a test to verify whether the connections among a plurality of IPs embedded in the semiconductor device on the electronic circuit board are correct, and whether the functions of IPs are appropriate. During a boundary scan test, boundary scan registers are activated for the test, and test signals for boundary scanning are input (shift in) to the input terminal of the electronic circuit board. The input test signals are sequentially processed by the IPs within the semiconductor device. The test signals processed by the IPs are output (shift out) from the output terminal of the electronic circuit board. The output test signals are verified to determine if they match the expected signals.

Meanwhile, a variety of IPs are provided by IP vendors in recent years. Among the IPs provided, there are those that require the IP to be in a specific state beforehand to execute a boundary scan test. When the semiconductor devices containing such IPs are implemented on an electronic circuit board, the IPs must be set to the specific state before initiating the boundary scan test. Specifically, setting the IP to the specified state is performing the TDR setting operation of the IP. The TDR setting operation required for such an IP depends on the type or specifications of the IP.

However, the JTAG standard does not allow the JTAG control circuit within the semiconductor device to perform the TDR setting operation for the IP during a period from when the electronic circuit board is powered on or rebooted to when the boundary scan test is initiated.

In light of the above circumstances, there is a demand for technology that enables the execution of tests specified by JTAG in semiconductor devices containing IPs requiring specific settings for testing.

### Related Semiconductor Device

In view of the above circumstances, the inventor first considered a related semiconductor device as illustrated below.

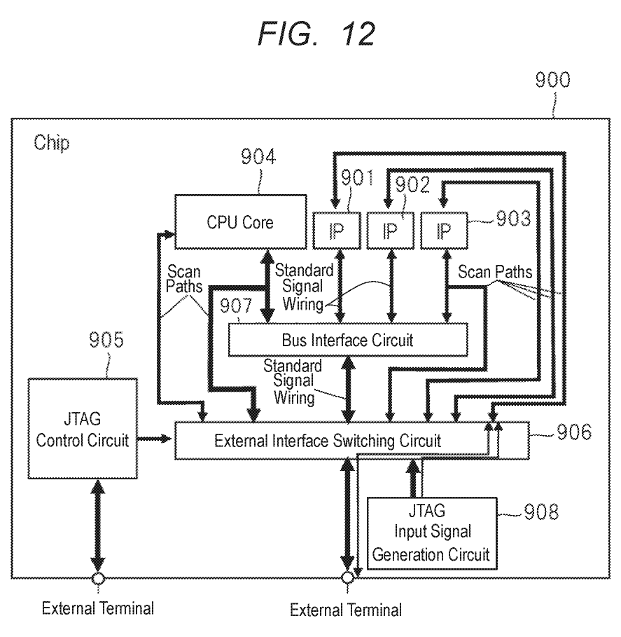

FIG. 12 is a diagram showing the configuration of a related semiconductor device. As shown in FIG. 12, a semiconductor device 900 includes a plurality of IPs. Here, the IPs include IP 901, IP 902, and IP 903. The semiconductor device 900 further includes a CPU core 904, a JTAG control circuit 905, an external interface switching circuit 906, a bus interface circuit 907, and a JTAG input signal generation circuit 908.

The CPU core 904, the external interface switching circuit 906, and the bus interface circuit 907 are interconnected via scan paths. The IP 901, IP 902, and IP 903 are connected to the bus interface circuit 907 via standard signal wirings. The bus interface circuit 907 and the external interface switching circuit 906 are connected via standard signal wirings. Additionally, the JTAG input signal generation circuit 908 and each IP are connected via scan paths.

After the power-on or reboot of the electronic circuit board on which the semiconductor device 900 is mounted, the JTAG control circuit 905 issues instruction signals and sends them to the external interface switching circuit 906. Upon receiving the instruction signals, the external interface switching circuit 906 selects and activates one scan path from among those connected to IP 901 to IP 903. For example, firstly, the scan path connected to IP 901 is selected and activated. The external interface switching circuit 906 sends the signal of the TDR setting data of IP 901 generated by the JTAG input signal generation circuit 908 through the activated scan path to complete the TDR setting operation of IP 901.

Once the TDR setting operation of IP 901 is completed, the external interface switching circuit 906 switches the activated scan path from the scan path of IP 901 to the scan path of IP 902. The external interface switching circuit 906 sends the signals of the TDR setting data of IP 902 generated by the JTAG input signal generation circuit 908 through the activated scan path to complete the TDR setting operation of IP 902. The external interface switching circuit 906 performs the TDR setting operation of IP 903 in the same manner.

In other words, the semiconductor device 900 is configured to sequentially activate a scan path for each IP requiring the TDR setting operation, send the TDR setting data for that IP through the activated scan path, and perform the IP's TDR setting operation.

Therefore, it is required a relatively long time for completing the TDR setting operations for all IPs and initiating the boundary scan test. In case that the semiconductor device includes numerous IPs requiring TDR setting operations prior to boundary scanning, a significant amount of time is required to complete the TDR setting operations for all IPs. Such semiconductor devices have low practicality.

Based on the above consideration results, the present inventor has newly devised the semiconductor device proposed in this disclosure. Below, the embodiment of the semiconductor device proposed in this disclosure will be described.

### FIRST EMBODIMENT

### Overview of the First Embodiment

First, an overview of the first embodiment will be described.

In the first embodiment, a sequencer is provided for each IP that requires the TDR setting operation before testing. Each sequencer responds to the instruction signal issued by the JTAG control circuit and automatically performs the TDR setting operation in parallel. Instead of the JTAG control circuit performing the TDR setting operations, each sequencer performs the TDR setting operation. Therefore, it is possible to perform boundary scan test as specified by JTAG on the semiconductor devices including IPs that each require the TDR setting operations, and on the electronic circuit board on which such semiconductor devices are mounted. Furthermore, the TDR setting operations for each IP are performed in parallel. Thus, compared to the related semiconductor devices where scan paths are switched for each IP to perform the TDR setting operations sequentially, the TDR setting operations for the plurality of IPs can be completed in a short time, enhancing the practicality of the semiconductor device.

### Detail of the First Embodiment

Next, the details of the first embodiment will be described.

### Configuration of Electronic Circuit Board Related to the First Embodiment

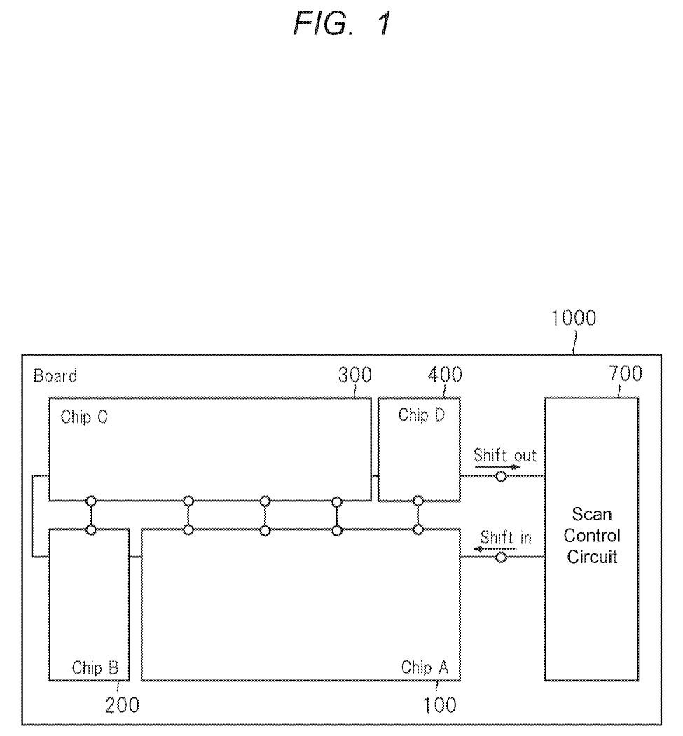

FIG. 1 is a diagram showing a configuration example of an electronic circuit board according to the first embodiment. As shown in FIG. 1, the electronic circuit board 1000 according to the first embodiment includes a plurality of semiconductor chips, a semiconductor chip 100 (Chip A), a semiconductor chip 200 (Chip B), a semiconductor chip 300 (Chip C), and a semiconductor chip 400 (Chip D). The electronic circuit board 1000 further includes a scan control circuit 700 to control the boundary scan test for the semiconductor chips based on an instruction from an external host computer. Each of the semiconductor chips 100 through 400 (Chip-A through Chip-D) is connected to adjacent semiconductor chips through paths. The scan control circuit 700 is provided inside the electronic circuit board 1000, but it may also be provided externally.

The semiconductor chip 100 includes a shift-in terminal for shifting in data. The semiconductor chip 400 includes a shift-out terminal for shifting out data. The shift-in and shift-out terminals are connected to the scan control circuit 700. After the electronic circuit board 1000 is powered on or rebooted, the scan control circuit 700 sends a boundary scan test execution instruction to the semiconductor chips mounted on the electronic circuit board 1000. The scan control circuit 700 then inputs test signal for boundary scan test to the shift-in terminal. The test signal is sequentially processed by the semiconductor chips 100 to 400, and the processed test signal is output from the shift-out terminal. The scan control circuit 700 determines whether there are any issues with the connection state or processing operation from the semiconductor chip 100 to the semiconductor chip 400 based on the processed test signal.

Here, the semiconductor chip 100 includes IPs that require setting a specific state in advance of performing boundary scan test, that is, IPs that each require TDR setting operation before performing the boundary scan test. TDR stands for test data register. Below, the focus is on semiconductor chip 100, and the configuration and operations of its components will be described.

### Hardware Configuration of Semiconductor Chip Related to the First Embodiment

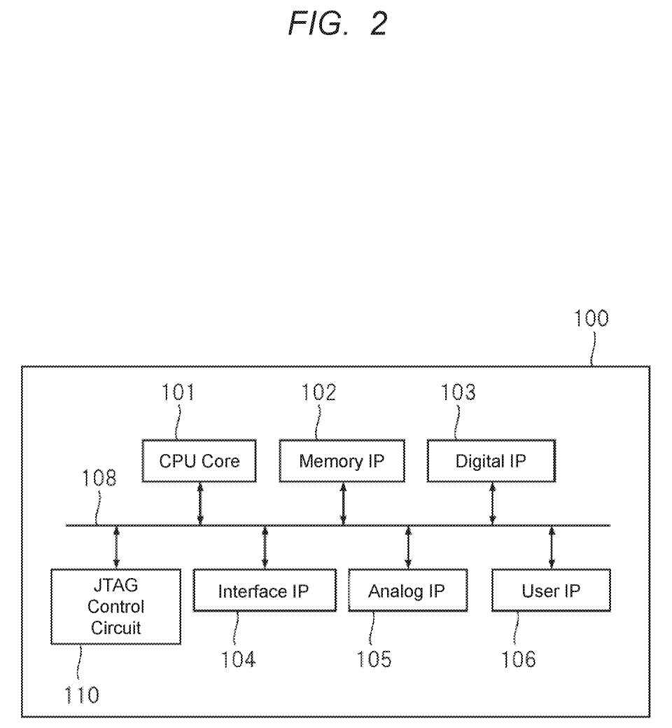

FIG. 2 is a diagram showing a hardware configuration example of the semiconductor chip according to the first embodiment. As shown in FIG. 2, the semiconductor chip 100 (Chip-A) according to the first embodiment has a CPU core 101, a bus 108, and a JTAG control circuit 110. The semiconductor chip 100 further includes various types of IPs, such as a memory IP 102, a digital IP 103, an interface IP 104, an analog IP 105, and user IP 106. The user IP 106 is a specific IP designed by the user. The CPU core 101, the IPs from 102 to 106, and the JTAG control circuit 110 are connected to bus 108.

### Functional Block Configuration of Semiconductor Chip Related to the First Embodiment

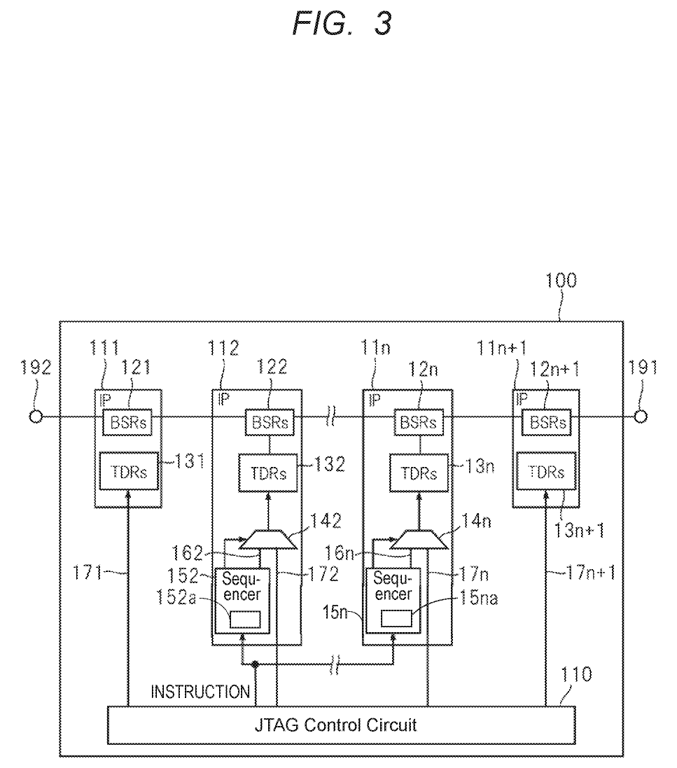

FIG. 3 is a diagram showing a functional block configuration example of the semiconductor chip according to the first embodiment. As shown in FIG. 3, the semiconductor chip 100 (Chip-A) according to the first embodiment has a plurality of IPs. Here, the IPs are referred to IP 111, IP 112, ..., IP 11n, IP 11n+1. Additionally, the semiconductor chip 100 has a JTAG control circuit 110. The JTAG control circuit 110 is coupled to the IP 111 via path 171. The JTAG control circuit 110 is coupled to the IP 112 via path 172. The JTAG control circuit 110 is coupled to the IP 11n via path 17n. Additionally, the JTAG control circuit 110 is coupled to the IP 11n+1 via path 17n+1. The paths 171, 172, ..., 17n, 17n+1 are used when debugging the IPs through the JTAG control circuit, respectively.

The JTAG control circuit 110 is controlled by the scan control circuit 700 shown in FIG. 1. The JTAG control circuit 110 controls the boundary scan tests of the IPs included in the semiconductor chip 100 in accordance with instructions from the scan control circuit 700. Specifically, the JTAG control circuit 110 issues instruction signals to the IPs upon receiving a boundary scan test execution instruction from the scan control circuit 700. Upon receiving a boundary scan test execution instruction from the scan control circuit 700, the JTAG control circuit 110 activates the boundary scan registers (BSRs; Boundary Scan Registers) of each IP for the boundary scan test. The instruction signals are control signals to activate the BSRs. Furthermore, the JTAG control circuit 110 performs control for semiconductor chip debugging according to instructions from the scan control circuit 700. The boundary scan register is an example of a "test circuit" in this disclosure.

Each of the IPs has test data register TDRs. The TDRs are used to set the state of the IP. For debugging, the state of the IP for debugging is set in the TDRs of the IP via an associated one of paths 171, 172, ..., 17n, 17n+1. The TDRs are also used for setting the IP state needed for using boundary scan registers BSRs before executing the boundary scan test. If the IP (e.g., IP 111 mentioned later) does not require status setting for using BSRs before executing the boundary scan test, its TDRs are used for debugging. If the IP (e.g., IP 112 mentioned later) requires state setting for using BSRs before executing the boundary scan test, its TDRs are used for debugging as well as for the boundary scan test.

Each of the IPs has BSRs. That is, the IP 111 has BSRs 121 and TDRs 131, while the IP 112 has BSRs 122 and TDRs 132. Additionally, the IP 11n has BSRs 12n and TDRs 13n, and the IP 11n+1 has BSRs 12n+1 and TDRs 13n+1. Adjacent IPs from IP 111 to IP 11n+1 are coupled, forming JTAG chains. An external terminal 191 is connected to one end of the JTAG chain, and an external terminal 192 is connected to the other end. One of the two external terminals 191 and 192 serves as the input for the boundary scan test signal, while the other serves as the output for the test signal. Each BSRs is enabled by JTAG control circuit 110, which receives boundary scan test execution instructions from the scan control circuit 700. In other words, each BSRs is activated as a test circuit for the boundary scan test by JTAG control circuit 110 upon receiving execution instructions.

Among the IPs included in semiconductor chip 100, the IPs that each require TDR setting operation before executing the boundary scan test are n-1 IPs including IP 112, ..., IP 11n. Here, IP 112 is focused upon as a representative for the IPs requiring TDR setting operation before executing the boundary scan test.

The IP 112 has, in addition to BSRs 122 and TDRs 132, a MUX 142 and a sequencer 152. The TDRs 132 is a test data register used to set the IP state enabling the BSRs 122. In other words, the TDR setting data set in the TDRs 132 determines the state of the IP 112.

The MUX 142 and the sequencer 152 are coupled via path 162. The sequencer 152 is coupled to the JTAG control circuit 110. The MUX 142 and the JTAG control circuit 110 are coupled via path 172. The sequencer 152 is configured to control the MUX 142 to selectively switch the input path of the MUX 142 between the path 162 of sequencer 152 and the path 172 of the JTAG control circuit 110.

The sequencer 152 holds the TDR setting data which is data indicating the set value to be configured in the TDRs 132 for the boundary scan test. The sequencer 152 receives an instruction signal from the JTAG control circuit 110. The sequencer 152 switches the input path of the MUX 142 to the path 162 of sequencer 152 in response to the instruction signal. Then, the sequencer 152 sends the TDR setting data to the TDRs 132 via the MUX 142. Upon completion of sending the TDR setting data, the sequencer 152 switches the input path of the MUX 142 to the path coupled with the JTAG control circuit 110, namely the path 172 as original interface side.

Each of IP from IP 113 (not shown) to IP 11n also has a configuration similar to the IP 112, and each component operates similarly. For example, in the case of the IP 11n, the IP 11n includes the TDRs 13n, a MUX 14n, and a sequencer 15n. The sequencer 15n and the MUX 14n are coupled via path 16n. The MUX 14n and the JTAG control circuit 110 are coupled via path 17n. Upon receiving the instruction signal from JTAG control circuit 110, the sequencer 15n switches the input path of the MUX 14n and sends TDR configuration data stored internally to the TDRs 13n. Upon completion of sending the TDR configuration data, the sequencer 15n switches the input path of MUX 14n to the path coupled with the JTAG control circuit 110, that is path 17n.

### Flow of Events or Processing in the Semiconductor Chip According to the First Embodiment

Below, the flow of processing in the semiconductor chip or electronic circuit board from power-on to boundary scan execution is described.

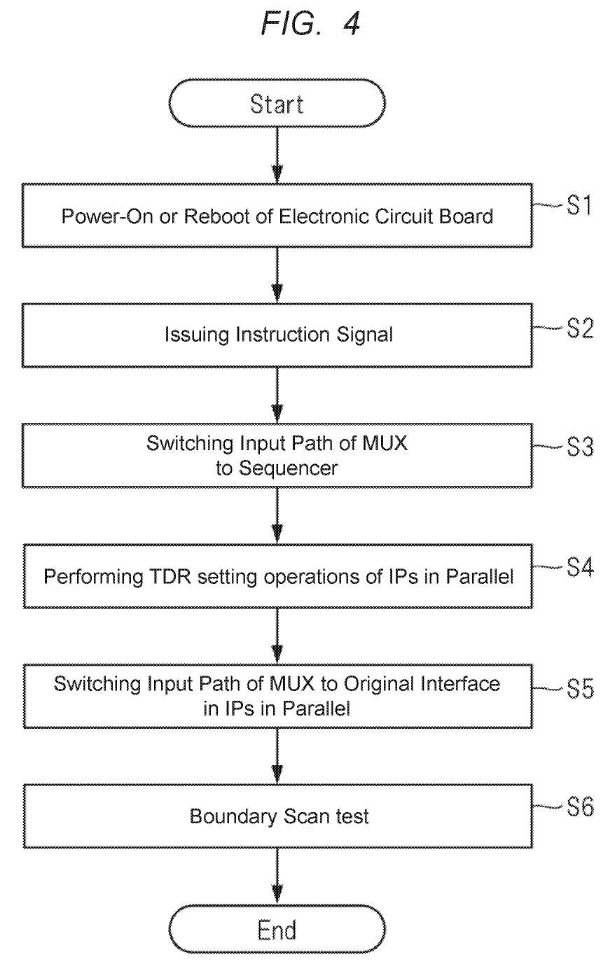

FIG. 4 illustrates the flow of processing in the semiconductor chip or electronic circuit board according to the first embodiment. The flow of processing is represented by steps S1 to S6, as shown in FIG. 4.

In step S1, power-on or reboot of electronic circuit board 1000 is performed. Specifically, for instance, a power-on operation or a reboot operation for the electronic circuit board 1000 or the device equipped with the electronic circuit board 1000 may be performed by the user.

In step S2, the JTAG control circuit 110 performs the process of issuing an instruction signal. Specifically, the JTAG control circuit 110 issues the instruction signal after receiving a boundary scan test execution instruction from the scan control circuit 700 following power-on or reboot of the electronic circuit board 1000. The instruction signal is also sent to each sequencer included in semiconductor chip 100 (Chip-A). For example, focusing on the IP 112, the JTAG control circuit 110 sends the instruction signal to the sequencer 152 after power-on or reboot of the electronic circuit board 1000. The BSRs included in the semiconductor chip 100 are activated based on the instruction signal.

In step S3, the sequencers in the IPs switch the input path of the MUX to the path connected to the sequencer in parallel. Specifically, upon receiving the instruction signal, each sequencer switches the input path of the MUX to the path connected to the sequencer. This processing by the sequencer is performed independently and concurrently across the IPs. For example, focusing on the IP 112, the sequencer 152 selects and activates the path 162 connected to the sequencer 152 as the input path for the MUX 142.

In step S4, each sequencer in the IPs performs TDR setting operation in parallel. Specifically, each sequencer sends the TDR setting data stored in the sequencer to the MUX using the activated path. Each MUX sends the received TDR setting data to subsequent TDRs. This completes the TDR setting operations for all TDRs. For example, focusing on the IP 112, the sequencer 152 sends the TDR setting data stored internally via path 162 to the MUX 142. The MUX 142 sends the received TDR setting data to subsequent the TDRs 132. This completes the TDR setting operation for the TDRs 132, the IP 112 is put in the specific state needed for boundary scan.

In step S5, each sequencer in the IPs switches the input path of the MUX to the original interface side. Specifically, each sequencer switches the input path of the MUX to the JTAG control circuit 110, that is, the original interface, upon completion of TDR setting operation. This operation by the sequencer is also performed independently and concurrently across the plurality of IPs. For example, focusing on the IP 112, the sequencer 152 selects and activates path 172 as the original interface to connect with the input path for the MUX 142.

In step S6, the boundary scan test is executed. Specifically, the scan control circuit 700 inputs a test signal from the shift-in terminal. The test signal input from the scan control circuit 700 is captured by the boundary scan registers forming the JTAG chain, and the test is executed. Then, scan control circuit 700 receives the processed test signal output from the shift-out terminal.

Note that step S6 is positioned after step S5 for convenience. However, the input of the test signal is not necessarily performed after the completion of TDR setting operations for all IPs. As will be described later, for example, the electronic circuit board or the semiconductor chip may be configured such that during transferring the test signal through the JTAG chain, the arrival of the test signal at the IP occurs after the IP's TDR setting operation is completed. In such a case, the boundary scan, i.e., the input of the test signal, may start without waiting for the completion of TDR setting operations for all IPs.

### Examples of Effects of the First Embodiment

The semiconductor device (semiconductor chip) according to the first embodiment comprises a plurality of functional blocks (IPs), a plurality of sequencers, and a control circuit (JTAG control circuit). Each of the functional blocks is a circuit designed to have a specific function. Each sequencer is provided for a corresponding functional block. The control circuit issues a signal (instruction signal) upon receiving an external test execution instruction (boundary scan test execution instruction) following power-on or reboot of the electronic circuit board on which the semiconductor device is mounted. Each functional block requires setting for test (boundary scan test) when the electronic circuit board is tested. Each sequencer responds to the signal to perform test setting operation (TDR setting operation) on the corresponding functional block. The semiconductor device (semiconductor chip) according to the first embodiment further includes test circuits (boundary scan registers) corresponding to each of the functional blocks (IPs). The signal issued by the control circuit (JTAG control circuit) receiving a test execution instruction may be a signal that activates the test circuit.

According to such a semiconductor device of the first embodiment, for example, the following effects can be obtained. In a semiconductor device that includes functional blocks requiring specific settings for test, sequencers automatically perform the specific settings instead of the control circuit, thus enabling compliance with JTAG-defined test executions. In other words, the control circuit does not need to receive instructions for setting the functional blocks. As a result, the test can be executed according to the JTAG standard. Additionally, specific test setting operations for the functional blocks can be performed in parallel, reducing the time to enable testing.

Furthermore, in the semiconductor device according to the first embodiment, each functional block includes a test data register (TDR). Moreover, the test setting operation involves storing test data in the test data register.

The test setting operation for functional blocks is often performed by storing data in the test data registers of the functional block. Therefore, such semiconductor devices propose highly versatile methods as test setting techniques for functional blocks before test operation.

In the semiconductor device according to the first embodiment, each of the functional blocks includes a first path, a second path, and a switching circuit. The first path is a path connecting the sequencer and the test data register. The second path is a path connecting the control circuit and the test data register. The switching circuit is a circuit that selectively activates one of the first path or the second path. Each sequencer controls the switching circuit such that the first path is activated when starting the test setting operation and the second path is activated when the test setting operation is completed.

In such a semiconductor device, the sequencer controls to connect the test data register to the sequencer only when setting functional blocks for testing. At other times, the sequencer controls to connect the test data register to the original interface. Thus, in functional blocks requiring test setting, path switching is automatically performed as needed, enabling efficient path switching control.

Furthermore, in the semiconductor device according to the first embodiment, the sequencer stores test data internally.

Therefore, the sequencer does not need to access external memory and can perform test setting operations for function blocks in a short time.

In addition, examples of the configuration and effects of the semiconductor device (semiconductor chip) according to the first embodiment can also be described more specifically as follows.

According to the first embodiment, each IP that needs to be in a specific state before the boundary scan test, that is, each IP that requires TDR setting operation, is equipped with a sequencer and a MUX. The MUX has two input paths and one output path. The output path of the MUX is connected to the TDRs. One of the two input paths of the MUX is connected to the sequencer, and the other is connected to the JTAG control circuit, i.e., the original interface side.

TDR setting data is stored in the sequencer. The sequencer is configured to activate the input path of the MUX connected to the sequencer in response to the instruction signal from the JTAG control circuit and transmit the TDR setting data to the TDRs via the MUX. Furthermore, the sequencer is configured to activate the input path on the original interface side of the MUX upon completion of the transmission of the TDR setting data.

With the above configuration, when the JTAG control circuit issues an instruction signal in response to a test execution instruction after power-on or reboot of the electronic circuit board, each sequencer automatically performs TDR setting operation. As a result, even when the semiconductor device mounted on the electronic circuit board includes IPs that require TDR setting before the boundary scan test, it is possible to perform TDR setting operation without processing for IPs by the JTAG control circuit. In other words, a semiconductor device having IPs that require TDR settings and the electronic circuit board on which the semiconductor device is mounted can perform a boundary scan conforming to JTAG standard.

Additionally, even if there are a plurality of IPs requiring TDR settings within the semiconductor device or electronic circuit board, the sequencer and MUX are provided for each IP requiring TDR setting. Then, each sequencer responds to the instruction signal from the JTAG control circuit and starts the operation simultaneously in parallel. Thus, the TDR setting operations for the IPs are performed concurrently, rather than sequentially for each IP. As a result, compared to a typical semiconductor device that switches paths for each IP and performs TDR setting operations sequentially, the TDR setting operations for the IPs can be completed in a short time, enhancing practicality.

### SECOND EMBODIMENT

### Overview of the Second Embodiment

First, an overview of the second embodiment will be described.

In the second embodiment, a memory for storing TDR setting data is provided on the semiconductor chip according to the first embodiment so that the TDR setting data can be variable. The memory is configured to store TDR setting data for each IP requiring TDR setting before the boundary scan. The sequencer is configured to read the necessary TDR setting data from the memory in advance and store it internally when performing TDR setting operation.

### Details of the Second Embodiment

The details of the second embodiment will be described below.

### Functional Block Configuration of the Semiconductor Chip according to the Second Embodiment

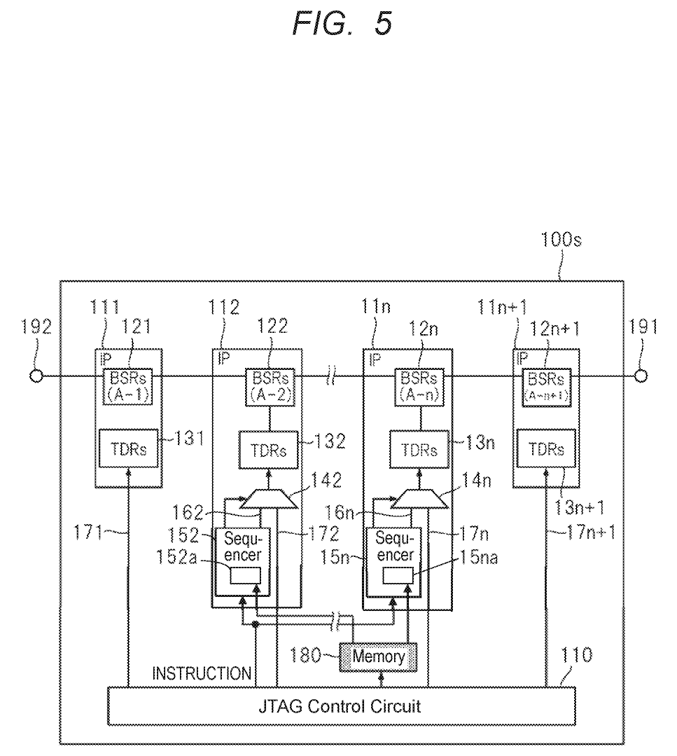

FIG. 5 is a diagram showing a functional block configuration example of a semiconductor chip according to the second embodiment. As shown in FIG. 5, the basic configuration of semiconductor chip 100s according to the second embodiment is the same as that of semiconductor chip 100 according to the first embodiment. However, semiconductor chip 100s further includes a memory 180 compared to semiconductor chip 100. The memory 180 is connected to the sequencer of each IP requiring TDR setting before the boundary scan, namely, n-1 IPs including IP 112, ..., and IP 11n. Memory 180 stores TDR setting data corresponding to each of IP112, ..., IP11n. The memory 180 may be, for example, a fuse memory, a flash memory, or a USB memory (registered trademark).

Here, as a representative of the IP requiring TDR setting before the boundary scan, we focus on the IP 112.

When the electronic circuit board 1000 is powered on or rebooted, the JTAG control circuit 110 issues a read command to the memory 180 according to the instructions from the scan control circuit. In response to the read command, memory data, which is the TDR setting data 152a for the TDRs 132, is read from the memory 180. The sequencer 152 stores the read memory data, i.e., the TDR setting data 152a for the TDRs 132, internally. After the sequencer 152 stores the TDR setting data 152a internally, the JTAG control circuit 110 issues an instruction signal and sends it to the sequencer 152.

When the TDR setting data 152a is stored internally in the sequencer 152, a series of processes for TDR setting operation is executed as in the first embodiment. Specifically, the sequencer 152 switches the input path of the MUX 142 to path 162 on the sequencer side and transmits the TDR setting data to the TDRs 132 via the MUX 142. Upon completion of the transmission of the TDR setting data, the sequencer 152 switches the input path of the MUX 142 to path 172 connected to the JTAG control circuit 110.

Each IP from IP 113 (not shown) to IP 11n also has the same configuration as the IP 112, with each component operating similarly. For example, in the case of IP 11n, the sequencer 15n reads memory data representing TDR setting data 15na for the TDRs 13n from the memory 180 upon receiving the instruction signal. The sequencer 15n stores the read memory data, i.e., the TDR setting data 15na for the TDRs 13n, internally.

Upon internal storage of TDR setting data 15na, the sequencer 15n switches the input path of MUX 14n and sends the internally stored TDR setting data 15na to the TDRs 13n. When the transmission of TDR setting data is completed, the sequencer 15n switches the input path of MUX 14n to path 17n connected to the JTAG control circuit 110.

### Process Flow in Semiconductor Chip According to the Second Embodiment

The process flow in the semiconductor chip or electronic circuit board from power-on to execution of boundary scans will be described below.

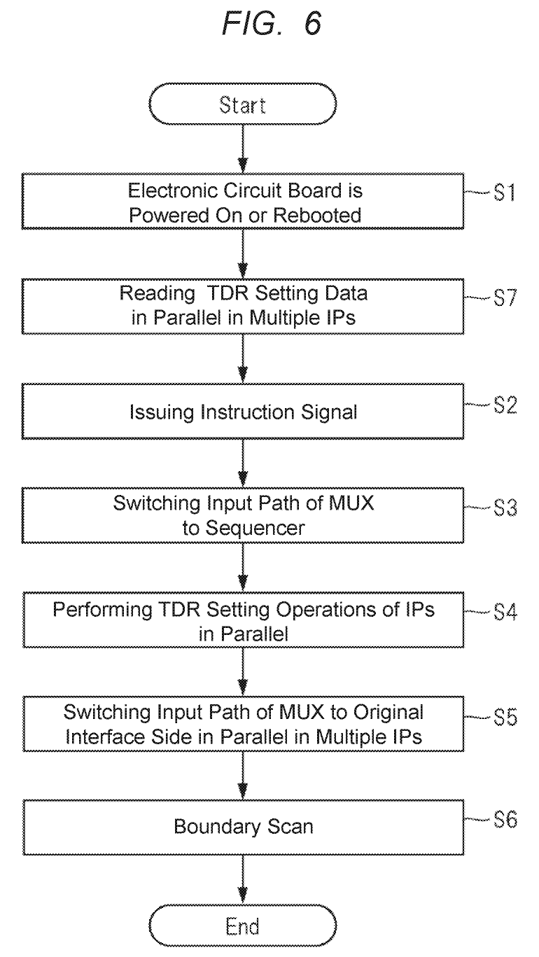

FIG. 6 is a diagram showing the process flow in a semiconductor chip or electronic circuit board according to the second embodiment. This process flow is represented from step S1 to step S7 as shown in FIG. 6. In the process flow according to the second embodiment, compared to the first embodiment, step S7 is added between step S1 and step S2. The rest is the same as in the first embodiment.

At step S1, the electronic circuit board 1000 is powered on or rebooted.

At step S7, each sequencer reads from the memory 180 the memory data representing the TDR setting data to be set for the corresponding TDRs and stores it internally.

Next, at step S2, the JTAG control circuit 110 issues an instruction signal.

Steps S4 to S6 are similar to those in the first embodiment, so a description of these steps will be omitted.

### Effects by the Second Embodiment

The semiconductor device according to the second embodiment includes memory for storing test data outside the plurality of sequencers. Furthermore, the sequencers each read test data from the memory.

According to such a semiconductor device, if it is necessary to change the test data later, the change can be easily made by rewriting the data stored in the memory or replacing the memory.

Moreover, in the semiconductor device according to the second embodiment, the memory can be configured to store multiple types of test data for at least one of the multiple function blocks. In this case, the sequencer corresponding to at least one of the function blocks selects and reads one from the multiple types of test data.

Thus, when the semiconductor device includes function blocks that can have multiple types of test settings, one of the multiple types of settings can be selected as needed for setting those function blocks.

Examples of the configuration and effects of a semiconductor device (semiconductor chip) according to the second embodiment can also be described more specifically as follows.

According to the second embodiment, a memory for storing TDR setting data is provided on the semiconductor chip. The memory is configured to store TDR setting data for each IP requiring TDR setting before the boundary scan test. The sequencer is configured to read the necessary TDR setting data from the memory in advance and store it internally when performing TDR setting operation.

The sequencer receiving an instruction signal may access the memory and read the TDR setting data. The TDR setting data read from the memory may be directly stored in the test data registers TDRs without being stored internally in the sequencer. This eliminates the time required to store the TDR setting data within the sequencer. As a result, the time required for TDR setting can be shortened.

The memory is expected to store TDR setting data for the plurality of IPs. However, the memory may be provided for each IP and store TDR setting data for a single IP. Additionally, the memory may store multiple candidates of TDR setting data for each IP, allowing the JTAG control circuit or the sequencer to select the candidate of setting data to be read according to need or circumstances.

With the above configuration, the TDR setting data can be made variable. For example, a change in TDR setting data may be required due to an IP version upgrade. Also, if it is found that the prepared TDR setting data contains errors, a change to correct TDR setting data might be required. Thus, if a change to the TDR setting data is desired later, accessing the memory and rewriting the TDR setting data within the memory is sufficient to effect the change. Additionally, if the memory is configured to be detachably mounted on the electronic circuit board, the TDR setting data can be changed by merely replacing the mounted memory with another memory that stores different TDR setting data.

### THIRD EMBODIMENT

### Overview of the Third Embodiment

First, an overview of the third embodiment will be described.

In the third embodiment, methods are devised to shorten the time from powering on or rebooting the electronic circuit board to starting boundary scan by optimizing the connection of semiconductor chips and IPs within the semiconductor chip. Preferably, the connection of the IPs is designed such that the TDR setting of an IP that requires TDR setting is completed before the test signals reach the IP. For example, on the electronic circuit board, the connection of semiconductor chips is designed to position the semiconductor chip having IPs that require TDR setting near the output of the test signals. Also, in the semiconductor chip, the connection of the IPs is designed to locate a IP with longer TDR setting data lengths near the output of the test signals.

### Details of the Third Embodiment

The details of the third embodiment will be described from here on.

### Configuration of the Electronic Circuit Board in the Third Embodiment

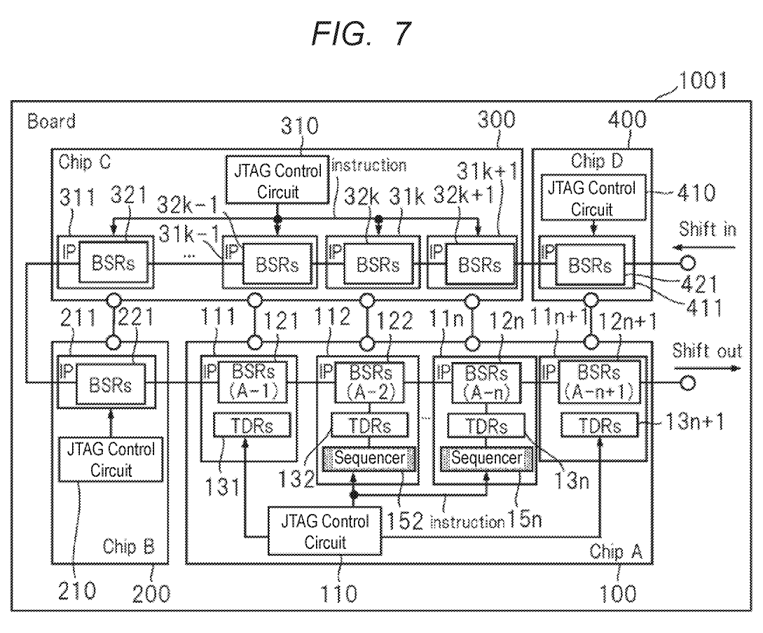

FIG. 7 is a diagram illustrating a configuration example of an electronic circuit board according to the third embodiment. As shown in FIG. 7, the electronic circuit board 1001 includes a semiconductor chip 400 (Chip D), a semiconductor chip 300 (Chip C), a semiconductor chip 200 (Chip B), and a semiconductor chip 100 (Chip A). In the electronic circuit board 1001, the semiconductor chip 400, the semiconductor chip 300, the semiconductor chip 200, and the semiconductor chip 100 are connected in this order from the shift-in side to the shift-out side.

The semiconductor chip 400 (Chip D) includes a JTAG control circuit 410 and an IP 411. The IP 411 includes BSRs 421.

The semiconductor chip 300 (Chip C) includes a JTAG control circuit 310 and a plurality of IPs that do not require TDR settings. These IPs are IP 31k+1, IP 31k, IP 31k-1, ..., IP 311. The IP 31k+1, IP 31k, IP 31k-1, ..., IP 311 are connected in this order. Each of these IPs includes BSRs 32k+1, BSRs 32k, BSRs 32k-1, ..., BSRs 321.

The semiconductor chip 200 (Chip B) includes a JTAG control circuit 210 and an IP 211 that do not require TDR setting. The IP 211 includes BSRs 221.

The semiconductor chip 100 (Chip A) includes a JTAG control circuit 110 and a plurality of IPs. The plurality of IPs include an IP that require TDR setting and an IP that does not require TDR setting. The plurality of IPs include IP 111, IP 112, ..., IP 11n, IP 11n+1. The IP 31k+1, IP 31k, IP 31k-1, ..., IP 311 are connected in this order. Each of these IPs includes BSRs 32k+1, BSRs 32k, BSRs 32k-1, ..., BSRs 321. Each of these IPs includes BSRs 121, BSRs 122, ...BSRs 12n, BSRs 12n+1.

Among these multiple IPs, those requiring TDR setting are IP 112, ..., and IP 11n. The IP 112, ..., 11n have the same configuration as the IPs requiring TDR setting as explained in the first embodiment. However, for simplicity in FIG. 7, within the IP 112, the TDRs 132 and the sequencer 152 are shown, while the MUX and the paths connected to MUX are omitted. Similarly, within the IP 11n, the TDRs 13n and the sequencer 15n are shown, while the MUX and the paths connected to MUX are omitted.

In the electronic circuit board 1001 according to the third embodiment, methods are devised to shorten the time from powering on or rebooting the electronic circuit board 1001 to initiating boundary scan by optimizing the connection layout of semiconductor chips. Here, in the electronic circuit board 1001, the connection layout of semiconductor chips is designed to position semiconductor chip 100 (Chip A), which includes IPs requiring TDR setting, near the output (shift out) of the test signals.

### Timing Chart of Signals in the Electronic Circuit Board of the Third Embodiment

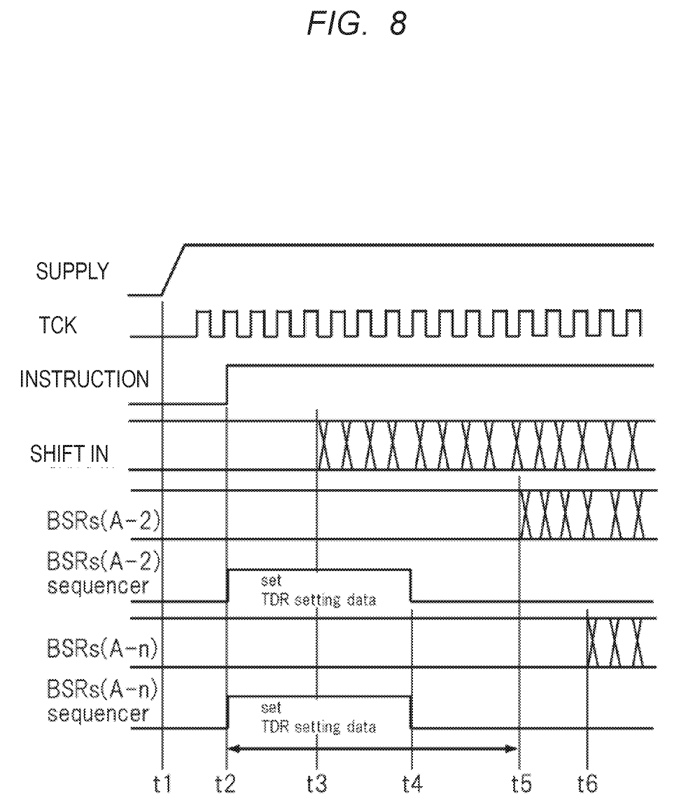

FIG. 8 is a timing chart of signals in the electronic circuit board 1001 according to the third embodiment. In the time chart shown in FIG. 8, "SUPPLY" represents the supply voltage and "TCK" represents the test clock signal. "INSTRUCTION" represents the instruction signal and "SHIFT IN" represents the input of the test signal for boundary scan. "BSRs(A-2)" represents signal processing based on the test signal at BSRs 122 and "BSRs(A-2) sequencer" represents the operation of the sequencer 152, i.e., TDR setting operation. Additionally, "BSRs(A-n)" represents signal processing based on the test signal at BSRs 12n and "BSRs(A-n) sequencer" signifies the operation of the sequencer 15n, i.e., TDR setting operation.

At time t1, the power supply to the electronic circuit board 1001 is turned on. Subsequently, the test clock TCK is generated and input into each semiconductor chip.

Each JTAG control circuit issues an instruction signal at time t2 after the power supply to the electronic circuit board 1001 is turned on. Then, each sequencer 152, ..., 15n in IP 112, ..., IP 11n begins the TDR setting operation. For example, the sequencer 152 corresponding to BSRs of the IP 112 and the sequencer 15n corresponding to BSRs of the IP 11n respectively start TDR setting operation. That is, the transmission of TDR setting data is initiated. Here, the TDR setting data length in the IP 112, ..., the IP 11n are assumed to be approximately the same.

At time t4, TDR settings for the IP 112, ..., IP 11n are completed. That is, the transmission of TDR setting data concludes.

Time t3 occurs between time t2 and time t4. At time t3, the test signal for boundary scan is input (SHIFT IN). At this point, TDR setting operation has not been completed yet. However, it is anticipated that in the IPs requiring TDR setting, the setting will be completed before the test signal reaches them. Therefore, it is possible to input the test signal without waiting for the completion of TDR setting.

At time t5, the test signal reaches the BSRs 122 of the IP 112. The test signal processed at the BSRs 122 is output to the next IP.

At time t6, the test signal reaches the BSRs 12n of the IP 11n. Subsequently, the test signal is processed by the final IP and then output (shifted out) from semiconductor chip 100.

Thus, in the electronic circuit board 1001, the connection layout of semiconductor chips is designed such that semiconductor chip 100, which includes IPs requiring TDR setting, is positioned near the output (shift out) of the test signal. Furthermore, it is anticipated that TDR setting in the IPs requiring TDR settings will be completed before the test signal reaches them. Thus, in the electronic circuit board 1001, the predetermined waiting time before inputting the test signal for boundary scan becomes unnecessary.

Consider the case where the connection layout of semiconductor chips cannot be designed to ensure TDR setting completion in IPs requiring TDR settings before the test signal reaches them. For example, consider a situation where a semiconductor chip on an electronic circuit board includes IPs requiring TDR settings cannot be positioned near the output (shift out) of the test signal and is instead positioned near the input (shift in).

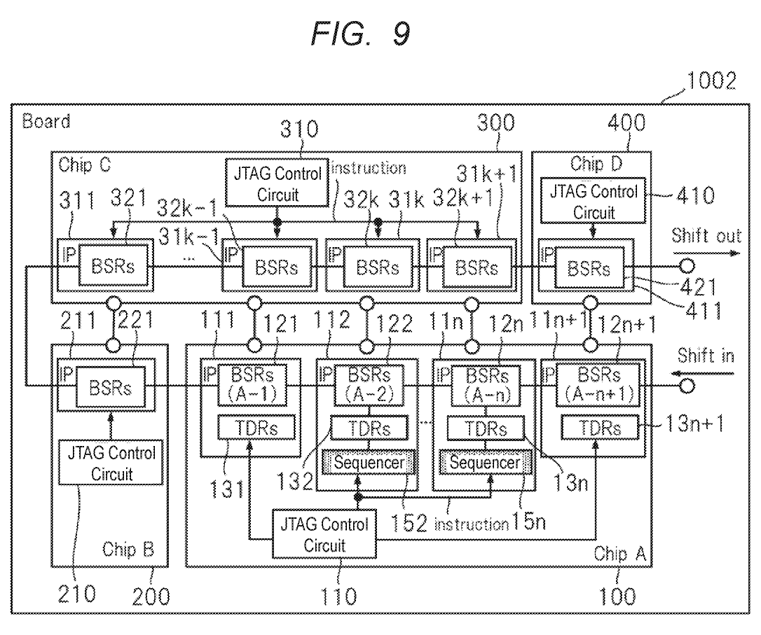

FIG. 9 is a diagram illustrating a configuration example of a comparison electronic circuit board according to the third embodiment. As shown in FIG. 9, the comparison electronic circuit board 1002 has the same components as the previously described electronic circuit board 1001. However, the connection layout of the semiconductor chips is different. Specifically, the semiconductor chips 100, 200, 300, and 400 are connected in this order from the input (shift in) of the test signal. In short, on the comparison electronic circuit board 1002, the semiconductor chip 100 having a IP that requires TDR setting is placed near the input (shift-in) of the test signal.

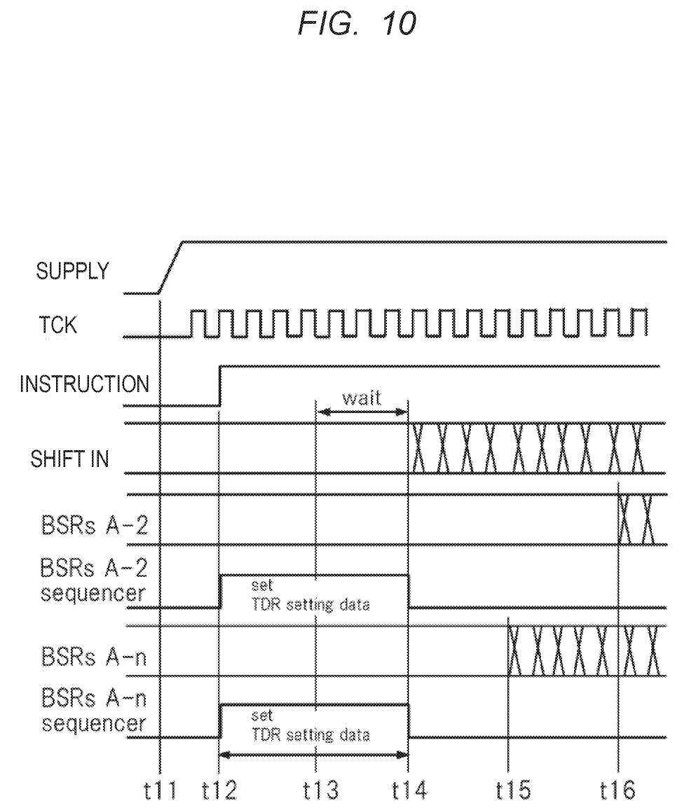

FIG. 10 is a timing chart of each signal on the comparison electronic circuit board 1002. Each signal in this timing chart is the same as the signals in the timing chart shown in FIG. 8.

At time t11, the power of electronic circuit board 1002 is turned on. Then, the test clock TCK is generated and input to each semiconductor chip.

At time t12, each JTAG control circuit issues an instruction signal upon receiving the power-on of electronic circuit board 1002. And each of the sequencer 152, ..., 15n in the IP 112, ..., 11n starts TDR setting.

At time t14, TDR setting is completed for the IP 112, ..., 11n. In other words, the transmission of TDR setting data is completed. Then, the test signal for boundary scan is input (shift-in). In the IPs requiring TDR setting, it is not expected that TDR setting will be completed before the test signal reaches. Therefore, the test signal cannot be input without waiting for the completion of TDR setting. The test signal is input after all TDR settings are completed.

At time t15, the test signal reaches the BSRs 12n of the IP 11n. The test signal processed at the BSRs 12n is output to the next IP.

At time t16, the test signal reaches the BSRs 122 of the IP 112. After that, the test signal is processed by the following IPs and then output (shift-out).

In the previous electronic circuit board 1001, special waiting time was not necessary until the test signal was input. Therefore, at time t13, which is between time t12 and time t14, the test signal is input. On the other hand, in the electronic circuit board 1002, the input of the test signal must wait until time t14 when all TDR settings are completed. In other words, a predetermined waiting time is required between time t13 and time t14. FIG. 10 shows the case where the TDR setting data lengths of the IP 112 and the IP 11n are the same. However, if the TDR setting data lengths of the IP 112 and the IP 11n are different, the predetermined waiting time may be set based on the time required for TDR setting of the TDR setting data with the longest data length.

As described above, even if the electronic circuit board requires a predetermined waiting time before the start of the boundary scan, the waiting time can be shortened or eliminated by devising the connection layout of the IPs within the semiconductor chip.

### Structure of the Semiconductor Chip According to the Third Embodiment

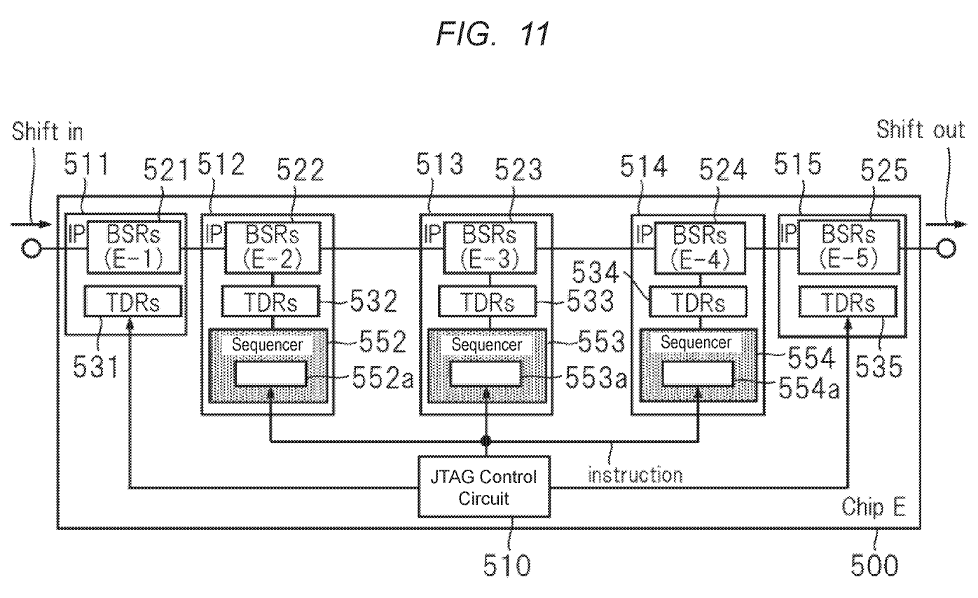

FIG. 11 is a diagram showing a configuration example of a semiconductor chip according to the third embodiment. As shown in FIG. 11, the semiconductor chip 500 (Chip E) according to the third embodiment has a JTAG control circuit 510 and a plurality of IPs. The IPs include the IP 511, the IP 512, the IP 513, the IP 514, and the IP 515. The IPs from the IP 511 to the IP 515 are connected in this order between the input (shift-in) and output (shift-out) of the test signal in the semiconductor chip 500. Here, among these IPs, those requiring TDR setting are from the IP 512 to the IP 514.

The IP 511 includes BSRs 521 and TDRs 531. The IP 512 includes BSRs 522, TDRs 532, and a sequencer 552. The sequencer 552 stores TDR setup data 552a. The IP 513 includes BSRs 523, TDRs 533, and a sequencer 553. The sequencer 553 stores TDR setup data 553a. The IP514 includes BSRs 524, TDRs 534, and a sequencer 554. The sequencer 554 holds TDR setting data 554a. The IP 515 includes BSRs 525 and TDRs 535. Note that in the IP 512 to IP 514, the description of MUX and the paths connected to MUX are omitted for simplicity.

The JTAG control circuit 510 issues instruction signals after the power on or reboot of the electronic circuit board on which the semiconductor chip 500 is mounted, according to boundary scan test execution instructions, and sends them to the sequencers 552, 553, and 554. The sequencers 552, 553, and 554 respectively respond to instruction signals, send the stored TDR setting data to TDRs, and perform TDR setting operation.

Arranging each TDR setting data in order of length, they are TDR setting data 554a, TDR setting data 553a, and TDR setting data 552a. Thus, within design possibilities, The IPs with longer TDR setting data are placed closer to shift-out terminal, and the IPs with shorter TDR setting data are placed closer to shift-in terminal. The time for TDR setting increases as the TDR setting data length increases. Therefore, if the IPs are connected and placed as described, it increases the likelihood that TDR setting can be completed before the test signal arrives at any IP, even when considering the semiconductor chip alone.

### Example of the Effects According to the Third Embodiment

In the semiconductor device according to the third embodiment, a plurality of function blocks are connected so that those test settings are completed before the input test signal arrives.

Thus, in the semiconductor device alone, it is not necessary to require a waiting time until the input of the test signal for testing. Therefore, the freedom of the connection layout of semiconductor devices on the electronic circuit board increases, making design easier. Additionally, even if the entire electronic circuit board requires the aforementioned waiting time, a reduction in waiting time can be expected.

Furthermore, more specifically, the configuration and effect examples of the semiconductor device (semiconductor chip) according to the third embodiment can be described as follows.

By devising the connection order of IPs that each requires TDR setting, it is possible to realize a semiconductor chip designed so that TDR setting is completed before the test signal reaches each IP that requires TDR setting. And such a semiconductor chip does not require consideration of the waiting time until the input of the test signal, regardless of how it is connected with other semiconductor chips on the electronic circuit board. Thus, according to such a semiconductor chip, the freedom regarding the connection layout of semiconductor chips on the electronic circuit board is increased, making it easier to design without requiring waiting time until the input of the test signal for boundary scan.

Although the invention made by the present inventor has been specifically described based on the embodiment, the present invention is not limited to the embodiment described above, and it is needless to say that various modifications can be made without departing from the gist thereof.

For example, in the above embodiment, the type of semiconductor chip or electronic circuit board is not particularly limited. However, a specific example of a semiconductor chip having IPs requiring TDR setting before boundary scan is DDR (Double Data Rate) PHY (PHYsical layer). The DDRPHY is a device that converts logical signals to electrical signals (D/A conversion) in DDR memory. In DDRPHY, there is a tendency to use a wide variety of IPs, with a high possibility of including IPs that require TDR setting. Therefore, the technology described in the above embodiment is particularly effective when applied to DDRPHY.

Additionally, in the above embodiment, the boundary scan test was explained as an example of "test" in the present invention, but it is not limited to this. The present invention is, needless to say, applicable to semiconductor chips (semiconductor devices) that include test circuits and function blocks requiring special setup for tests using those test circuits.

What is claimed is:

1. A semiconductor device comprising:
a control circuit configured to generate a signal in response to a test execution instruction, and
a plurality of function blocks,
wherein at least one of the plurality of function blocks is a first function block having a sequencer and being configured to require a test setting before executing a test,
wherein the sequencer is configured to receive the signal generated by the control circuit and perform a test setting operation for the first function block in response to the signal.

2. The semiconductor device according to claim 1,
wherein the first function block has a test data register that stores test setting data.

3. The semiconductor device according to claim 1,
wherein the first function block further includes a first test circuit that is activated based on the signals generated by the control circuit according to the test execution instruction.

4. The semiconductor device according to claim 2,
wherein the first function block further includes:
a first path for connecting the test data register and the sequencer;
a second path for connecting the test data register and the control circuit, and
a switching circuit selectively activating the first or the second path based on a control of the sequencer,
wherein the first path is activated when the test setting operation is performed, and the second path is activated after the test setting operation has been completed.

5. The semiconductor device according to claim 2,
wherein the sequencer stores the test setting data.

6. The semiconductor device according to claim 2, further comprising a memory for storing the test setting data,
wherein the sequencer is configured to read the test setting data from the memory.

7. The semiconductor device according to claim 6,
wherein the memory stores a plurality of types of test data, and the sequencer selects and reads one of the plurality of types of test data.

8. The semiconductor device according to claim 3,
wherein the control circuit comprises a JTAG control circuit, the test is a boundary scan test, and the first test circuit includes boundary scan registers for performing the boundary scan test.

9. The semiconductor device according to claim 1, further comprising:
a test signal input terminal, and
test signal output terminal,
wherein the other one of the plurality of function blocks is a second function block having a second test circuit,
wherein the first and the second test circuit are coupled to each other between the test signal input terminal and the test signal output terminal so that the test setting for the first function block has been completed before an input test signal from the test signal input terminal reaches the first test circuit.

10. The semiconductor device according to claim 1,
wherein the first function block comprises DDRPHY.

11. A semiconductor device comprising:
a JTAG control circuit configured to generate an instruction signal in response to a test execution instruction;
a plurality of function blocks including a first function block;
a test signal shift in terminal, and
a test signal shift out terminal,
wherein the first function block includes:
a test data register configured to set a status of the first function block;
a boundary scan register coupled between the test signal shift in terminal and the test signal shift out terminal and receiving a test signal through the test signal shift in terminal, and
a sequencer configured to store test setting data and send the test setting data to the test data register in response to the instruction signal from the JTAG control circuit to set the status of the first function block for the boundary scan test.
